(19) United States
(12) Patent Application Publication
(10) Pub. No.: US 2012/0282767 A1
(43) Pub. Date: Nov. 8, 2012

(54) METHOD FOR PRODUCING A TWO-SIDED FAN-OUT WAFER LEVEL PACKAGE WITH ELECTRICALLY CONDUCTIVE INTERCONNECTS, AND A CORRESPONDING SEMICONDUCTOR PACKAGE

(75) Inventors: Yonggang Jin, Singapore (SG); Yun Liu, Singapore (SG); Puay Gek Chua, Singapore (SG); Anandan Ramasamy, Singapore (SG); Yaohuang Huang, Singapore (SG); Kah Wee Gan, Singapore (SG)

(73) Assignee: STMicroelectronics Pte Ltd., Singapore (SG)

(21) Appl. No.: 13/173,991

(22) Filed: Jun. 30, 2011

Related U.S. Application Data
(60) Provisional application No. 61/482,969, filed on May 5, 2011.

(51) Int. Cl. H01L 21/60

(52) U.S. Cl. 438/613; 257/E21.508

(57) ABSTRACT

A semiconductor packaging process includes drilling apertures in a reconstituted wafer, then filling the apertures with conductive paste by wiping a quantity of the paste across a back surface of the wafer so that paste is forced into the apertures. The paste is cured to form conductive posts. The wafer is thinned, and redistribution layers are formed on front and back surfaces of the wafer, with the posts acting as interconnections between the redistribution layers. In an alternative process, blind apertures are drilled. A dry film resist is applied to the front surface of the wafer, and patterned to expose the apertures. Conductive paste is applied from the front. To prevent paste from trapping air pockets in the apertures, the wiping process is performed under vacuum. After curing the paste, the wafer is thinned to expose the cured paste in the apertures, and redistribution layers are formed.

### BACKGROUND OF THE INVENTION

1. Technical Field

This disclosure is related to the manufacture of semiconductor devices, and in particular, the manufacture of fan-out wafer level packaging of semiconductor dies.

2. Description of the Related Art

Fan-out wafer-level packaging is a packaging process in which contacts of a semiconductor die are redistributed over a larger area. FIG. 1 shows a cross sectional diagram of a package-on-package (PoP) assembly 100 that includes a fan-out wafer level package (FOWLP) 102 and a plurality of additional semiconductor devices 104 coupled thereto.

The FOWLP 102 includes a semiconductor die 106 embedded in a molding compound layer (MCL) 108, with a first redistribution layer 110 positioned on a first face 111 of the MCL and a second redistribution layer 113 positioned on the opposing second face 115. The first redistribution layer 110 comprises a plurality of electrical traces 112 and vias 114 separated by dielectric material 116, which place contact pads 118 of the die 106 in electrical contact with contact pads 120 of the package 102. Additionally, through-wafer vias (TWV) 122 in the MCL 108 place various of the plurality of electrical traces 112 in electrical contact with corresponding elements of the second redistribution layer 113. The second redistribution layer 113 includes contact pads 134, sometimes referred to as landing pads, because they are configured to receive solder connections from additional devices coupled to the FOWLP 102. A first ball grid array (BGA) comprises a plurality of solder balls 126 positioned on respective ones of the contact pads 120, which, during a reflow process, will serve to electrically and mechanically couple the package 102 to a printed circuit board.

In the example of FIG. 1, the plurality of additional semiconductor devices 104 includes devices 128 in which through-silicon vias (TSV) 130 are provided according to known processes. Each of the additional semiconductor devices 104 is provided with a respective BGA 136 to couple contact pads 132 of that device to contact pads 134 of the device on which it is positioned.

Configurations like the PoP assembly 100 of FIG. 1 provide a number of advantages over traditionally packaged devices, including reduced manufacturing costs and reduced size. Such packaging is particularly beneficial in very small and complex electronic devices, including, for example, cell phones and “smart” phones.

In manufacturing devices such as the FOWLP 102, a number of processes are known for use in providing the TWVs 122 in the MCL 108.

According to one method, conductive bumps are printed onto a carrier substrate on which the semiconductor material die 106 is later positioned, and both are then embedded in molding compound. This process is described in detail in U.S. Pat. No. 6,714,418.

According to another method, TWVs are formed using techniques similar to those commonly used to form plated through-holes in printed circuit boards, as described, for example, in U.S. Pat. No. 7,598,607.

Electrically conductive paste is a polymeric material that includes a conductive ingredient. It is sometimes used in the manufacture of printed circuit boards (PCB) to fill through-holes and blind vias. Conductive paste is typically applied by screen printing, metal foil stencil, roller coating, or with a doctor blade. A vacuum assist is often used to draw the paste through the holes. In this manner, holes having high aspect ratios can be filled. Where conductive paste is used to fill blind vias, the aspect ratio of the holes must be low, generally less than 1:1, to permit the paste to fill the holes without trapping significant quantities of air. Deposition of conductive paste typically leaves a bump or blob of paste on one or both faces of a board or layer, so except where such a bump will not interfere with subsequent assembly steps, circuit boards or lamina are either wiped clean, if that can be done prior to curing the paste, or they are planarized or polished after curing.

Dry film resist is a photosensitive film that is most commonly used in the manufacture of printed circuit boards as a plating mold in the process of depositing copper wiring patterns. Dry film resist is available in a wide range of thicknesses and formulations, typically consisting of three layers: a transparent polyester support layer, a resist layer, and a polyethylene cover layer.

In use, the polyethylene cover layer is first removed, then the film is positioned with the resist side against a substrate, e.g., a resin substrate for a circuit board, under controlled pressure at a temperature of around 100 degrees C., to cause the resist layer to adhere to the surface of the substrate. The film is commonly applied using a roller or a vacuum press to apply the pressure. A mask is then positioned over the polyester support layer and the film is exposed to a light source. In the case of a positive-acting film, the portions of the film that are exposed to the light will dissolve and wash away during a subsequent developing process, and in the case of a negative acting film, the non-exposed portions will be removed during developing. After exposure to the light, the mask is removed, and the polyester support layer is peeled away, leaving the resist layer on the surface of the substrate. The resist layer is developed, by a process that varies according to the variety of film used, to remove the portion of the resist layer that is not desired, leaving the patterned layer behind. Where the dry film resist is used as a plating resist, a seed layer is typically deposited on the substrate prior to deposition of the film. After the film layer is patterned, the substrate is electroplated with copper, which adheres to the substrate at the locations where removal of the resist layer has exposed the seed layer. Following the plating step, the resist layer is removed, leaving a copper circuit pattern formed on the substrate of the circuit board. Lastly, a short etch step removes a thickness of copper slightly in excess of the thickness of the seed layer, which is thereby removed from the substrate.

Dry film resist is also occasionally used as an etch resist when circuit boards are made by a subtractive process, and has also been investigated experimentally for use as a plating mold in the manufacture of MEMS devices. Dry film resist is commonly available in thicknesses (of the resist layer) ranging from around 15 μm (microns) to 75 μm, with thicknesses up to around 200 μm being used in the MEMS investigations.

### BRIEF SUMMARY

According to an embodiment, a process for manufacturing semiconductor packages includes drilling a plurality of apertures through a reconstituted wafer in which a plurality of semiconductor dies are embedded, and filling the apertures with conductive paste. Factors affecting the depth of penetration of the conductive paste are controlled so that the paste fills the apertures without extruding large quantities of paste out the opposite ends of the apertures. The paste is then cured in the apertures to form conductive posts within the apertures, traversing the thickness of the wafer. Redistribution layers are then formed on opposite faces of the wafer, elements of each redistribution layer making contact with the conductive posts to permit electrical signals to travel from one RDL to the RDL on the opposite face of the wafer.

### BRIEF DESCRIPTION OF THE SEVERAL VIEWS OF THE DRAWINGS

FIG. 1 is a cross sectional diagram of a package-on-package assembly including a fan-out wafer-level semiconductor package, according to known art.

FIGS. 2-4 are cross-sectional diagrams showing respective steps in forming a reconstituted wafer, as part of a process of manufacturing a fan-out wafer level package according to an embodiment.

FIGS. 5-12 are cross-sectional diagrams showing enlarged views corresponding, approximately, to a portion of the wafer of FIG. 4 between lines 5-5 of FIG. 4, each figure showing a respective stage of the manufacturing process.

FIGS. 13-16 are cross-sectional diagrammatic views of a portion of a reconstituted wafer at respective stages of a manufacturing process according to another embodiment.

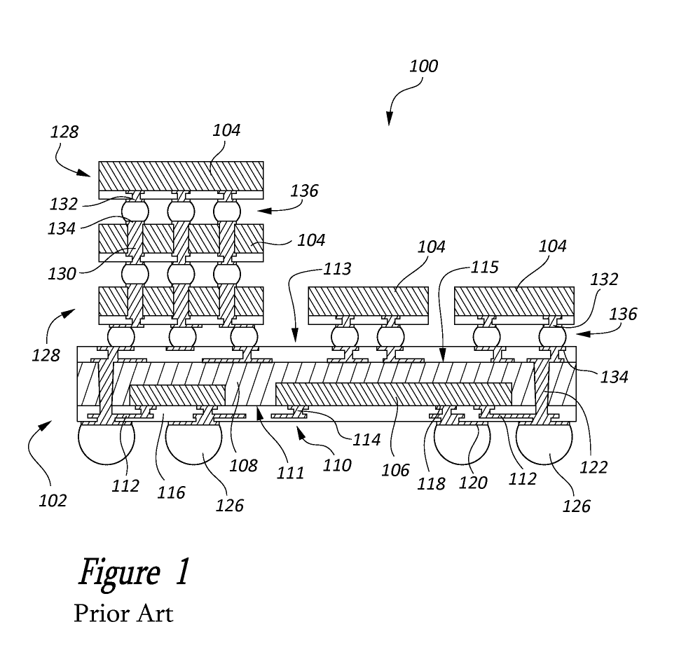

### DETAILED DESCRIPTION

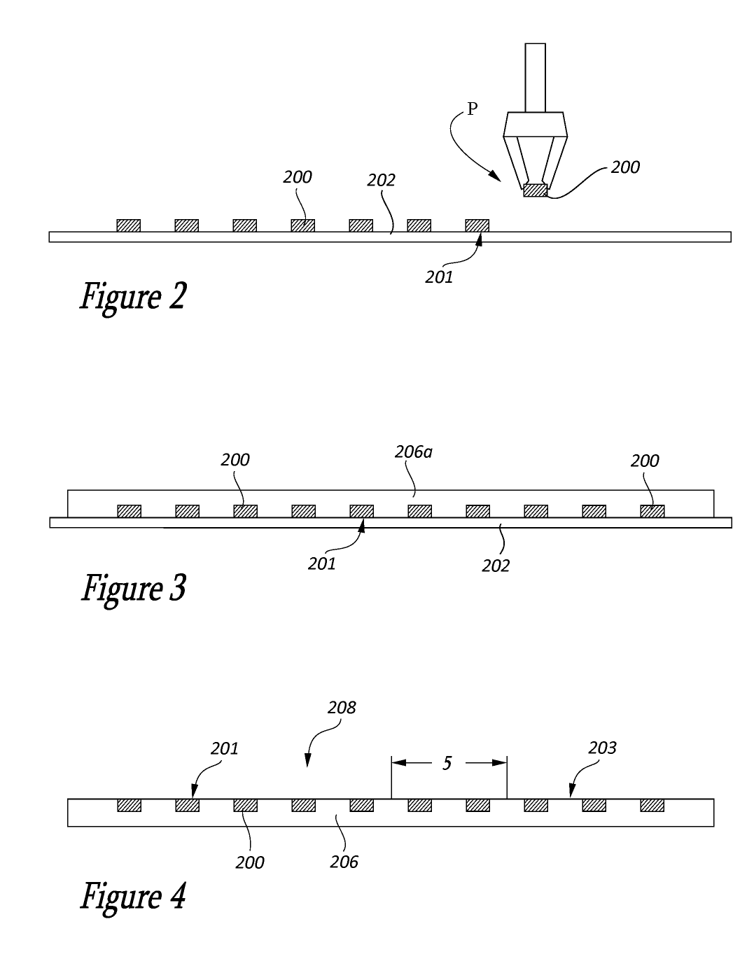

A process for the manufacture of a FOWLP according to one embodiment is described with reference to FIGS. 2-14. Prior to the packaging process described below, a semiconductor wafer is processed according to known methods to form integrated circuits and other devices. Typically, such circuits are formed in a single face of the wafer, which is typically referred to as the active face or front face.

When processing of the semiconductor wafer is complete, the wafer is cut into individual dice, each of which includes a respective plurality of contact pads on its front face, for electrical contact with the circuit or system integrated therein. Referring first to FIG. 2, individual dice 200 are shown, positioned front face 201 down on a carrier sheet 202 that has an adhesive surface, using a “pick-and-place” operation P, in which each die is precisely positioned relative to the other dice on the carrier 202. The adhesive surface holds the dice in their respective positions during subsequent process steps.

A reconstituted wafer 208, shown in FIG. 3, is made by depositing a molding compound 206a over the dice 200 on the carrier sheet 202, which is cured under pressure to form a molding compound layer (MCL) 206 that becomes the primary substrate of the reconstituted wafer 208. Typically, the molding compound layer is around 500 μm to 750 μm after curing. After the molding compound is cured, the carrier sheet 202 is removed, as shown in FIG. 4, leaving the front faces 201 of the dice exposed and lying substantially in a common plane with a front face 203 of the reconstituted wafer 208. A reconstituted wafer can be made in any shape or size, depending on the number, spacing, and arrangement of the dice on the carrier sheet, but typically is made to conform in size and shape to a standard semiconductor material wafer, so that equipment designed for transporting and processing semiconductor wafers can be used to process reconstituted wafers that have semiconductor material dice embedded in an MCL.

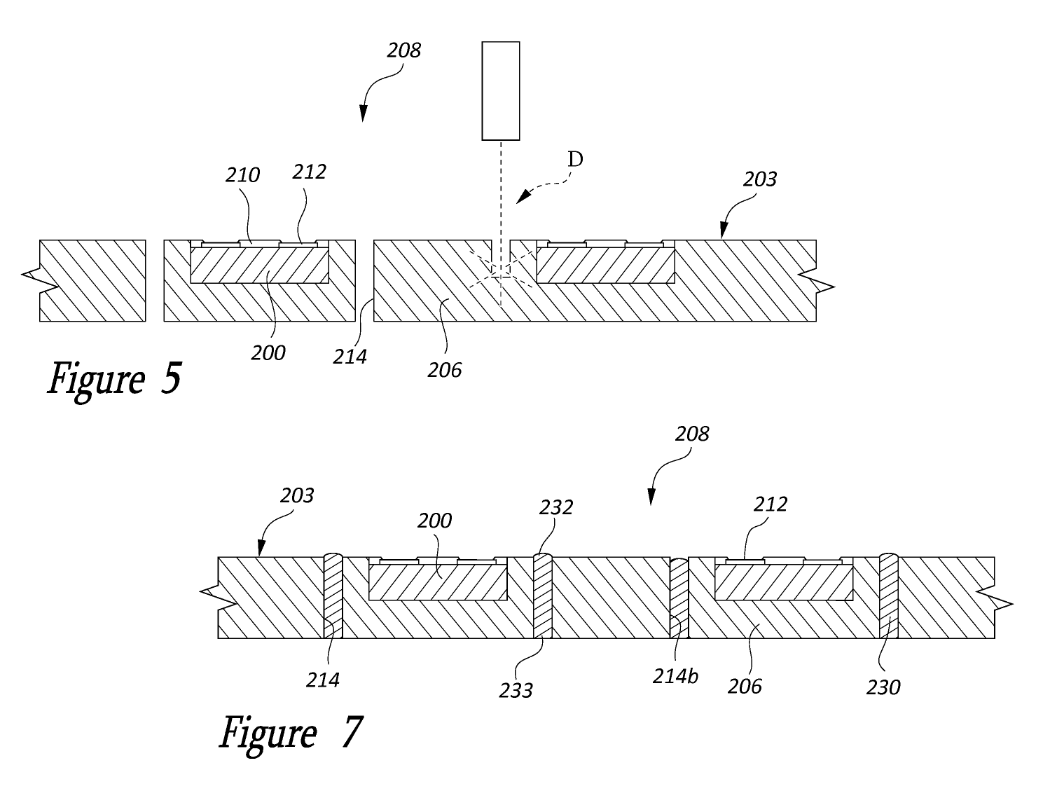

FIGS. 5-12 show, in an enlarged view, a small portion of the reconstituted wafer 208 at various stages of processing, the enlarged view corresponding, approximately, to the portion of the wafer between the lines indicated at 5 in FIG. 4.

In FIG. 5, dice 200 are shown, each having a plurality of contact pads 210 and a passivation layer 212. After removal of the carrier 202, through apertures 214 are drilled into the MCL 206. The apertures 214 can be formed by laser drilling 216, as shown in FIG. 5 at D, or by any other appropriate process, including chemical, mechanical, or electrical processes. The apertures are preferably on the order of 5-15 μm in diameter, but may be either larger or smaller, as required.

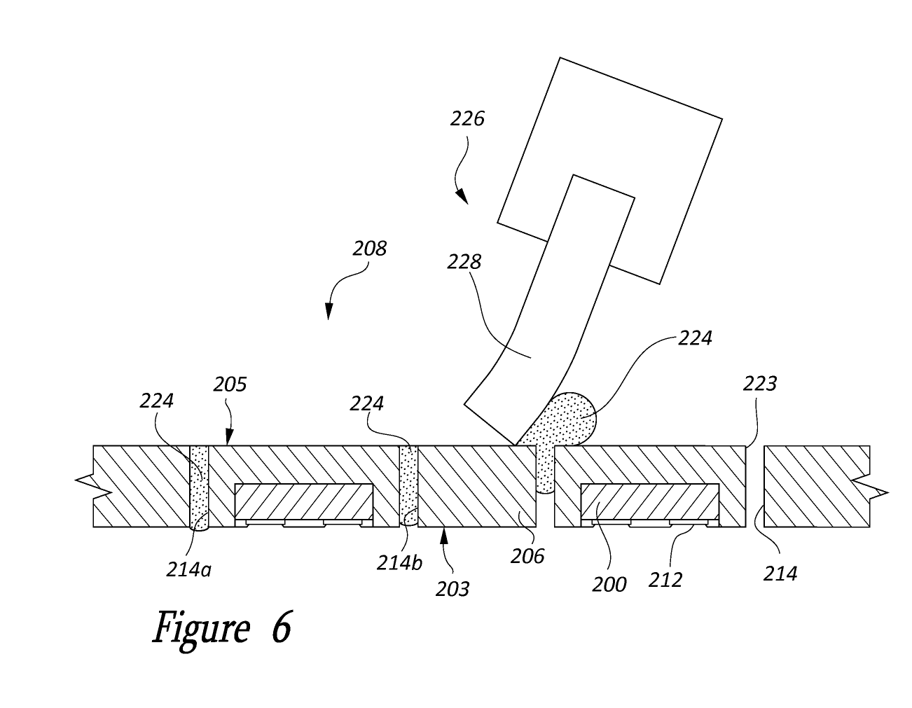

As shown in FIG. 6, a quantity of conductive paste 224 is placed on the back face 205 of the wafer 208. A squeegee 226 with a resilient elastomeric blade 228 is drawn across the back face 205 of the wafer 208, pulling a bead of conductive paste 224 across the face. A sharp edge of the blade 228 acts as a wiper to leave the back of the wafer substantially clean except where the paste 224 is drawn across openings 223 of the apertures 214 in the back face of the wafer 208. At these locations, the conductive paste 224 is forced into the apertures 214 by the action of the squeegee 226, so that a column of conductive paste penetrates the apertures substantially the entire thickness of the reconstituted wafer. Preferably, the paste penetrates to the front face 203 of the wafer 208 so that the column of paste within each aperture 214 has a face that lies within an acceptable distance of the front face of the wafer, more preferable so that the front face of each column lies substantially within a plane defined by the front face of the wafer. In FIG. 6, the paste is shown to form a slight dome on the front face 203 of the wafer 208 in the first aperture 214a, and to extend slightly short of the front face in the second aperture 214b, both of which are acceptable, at least under conditions described below.

Viscosity, rheology, surface tension, and solid content of the conductive paste 224, hardness of the blade 228, pressure and speed at which the blade moves, the angle of the blade relative to the back face of the wafer, and diameter of the apertures 214 are all factors that affect the depth to which the paste penetrates the apertures. By control of these and other such factors, and by selection of the thickness of the wafer 208, the conductive paste 224 can be made to penetrate the apertures 214 the entire thickness of the reconstituted wafer. Additionally, a vacuum assist can be used to draw the conductive past into the apertures 214. In a vacuum assist, a controlled level of relative vacuum is applied to the front face 203 of the wafer 208, either while the paste 224 is introduced into the apertures 214 by the blade 228, or immediately thereafter. The degree and duration of vacuum is controlled to provide an amount of additional force necessary to entirely fill the apertures 214 with paste. The vacuum assist described here differs from that referred to in the background in that the degree of vacuum is closely controlled, and the timing and duration are defined with reference to the application of the paste to the back face 205 of the wafer 208 by the blade 228.

After the conductive paste 224 is loaded into the apertures 214, the paste is cured and hardened to form a conductive post 230, as shown in FIG. 7. Each conductive post 230 has a front end 232 that is approximately coplanar with the front face 203 of the wafer 208, and a back end 233 that is approximately coplanar with the back face 205 of the wafer. Typically, the conductive paste 224 is formulated using a thermosetting polymer, so curing the paste is accomplished by application of heat. Alternatively, the paste 224 may be a thermoplastic material that is melted prior to application and that re-hardens upon cooling, or it may cure in reaction to a catalyst that is mixed just prior to application, or by oxidation through contact with air, or by any other appropriate process.

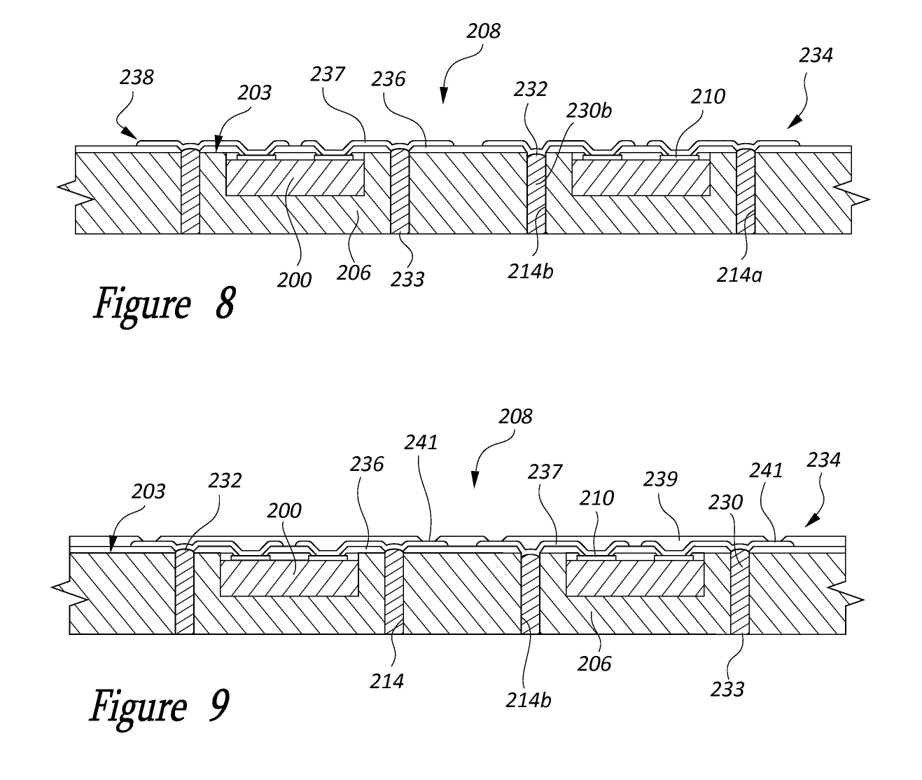

Following the curing of the conductive paste, a first redistribution layer (RDL) 234 is formed on the front face of the wafer 208 using processes that are well known in the art. As shown in FIG. 8, a first dielectric layer 236 is deposited, and patterned. A conductive layer 238 is then deposited over the first dielectric layer 236, and patterned to form a plurality of electrical traces 237 in a pattern selected according to the configuration and function of the particular device being made. Individual ones of the electrical traces 237 make contact with the contact pads 212 of the semiconductor dice 200 and with the front ends 232 of the conductive posts 230. In the example shown in FIG. 8, each of the contact pads 212 of the semiconductor dice 200 is electrically coupled to a respective one of the conductive posts 230 by a corresponding electrical trace 237. Materials used to form conductive layers like the layer 238 generally have some conformability, and can accommodate some variations in thickness of contact pads. Accordingly, provided the heights of the front ends 232 of the conductive posts 230 are within acceptable tolerances, the conductive layer 238 will make adequate electrical contact, as shown relative to the post 230b in aperture 214b. The controlling tolerance will be determined by factors that include the material selected for the conductive layer and the process used to deposit the layer. Such considerations are well known in the art.

As shown in FIG. 9, a second dielectric layer 239 is deposited over the conductive layer 238 and patterned to define contact pads 241. The first RDL 234 is further processed according to the particular requirements of the device, and according to well known processes. These processes can include deposition of additional dielectric and metal layers, formation of passive components, contact pads, ball grid arrays, etc. The arrangement of the elements of the wafer 208 and first RDL 234 is for the purpose of illustration and example only. In actual practice, the elements are configured according to a particular application, and will certainly differ significantly from the arrangement shown.

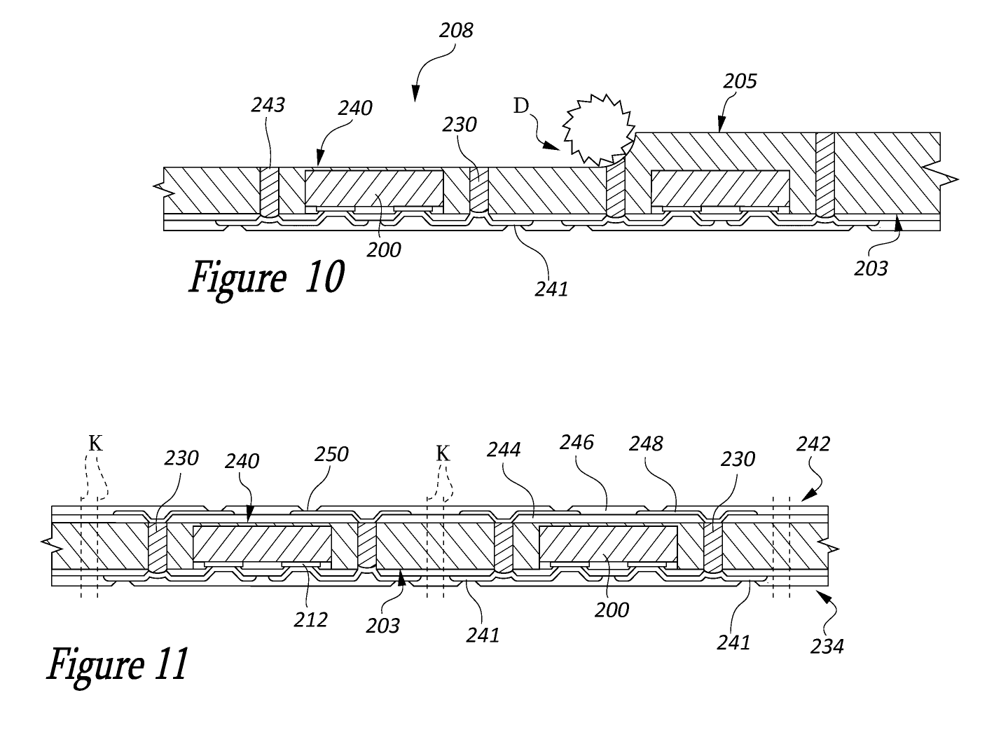

Following the curing of the conductive paste 224 in the apertures 222, the back side of the reconstituted wafer 208 can be thinned to a desired thickness, as shown in FIG. 10, producing thereby new back ends 243 of the conductive posts, and a new back surface 240 of the wafer 208. Alternatively, the wafer 208 can be thinned or partially thinned prior to depositing the conductive paste as described with reference to FIG. 6, or the thinning process can be omitted. The final thickness of the wafer 208 is preferably around 250 pm to 400 pm, but can be any acceptable thickness. The thinning process can be performed using any appropriate process or combination of processes, such as are well known in the art. For example, the reconstituted wafer can be thinned by polishing, CMP, milling, etching, grinding or any acceptable technique. The diagrammatic view of FIG. 10 depicts a mechanical grinding process G, but this is merely exemplary.

As shown in FIG. 11, a second RDL 242 is formed on the back face 240 to redistribute connections to the conductive posts 230. In the example illustrated in FIG. 11, the second RDL is formed using process steps that correspond to those described with reference to the first RDL 234. The second RDL includes first and second dielectric layers 244, 246 and a conductive layer 248 positioned between. Landing pads, 250 are defined, and placed in electrical contact with respective conductive posts 230 by electrical traces of the conductive layer 238. It will be recognized that the arrangement shown is again merely exemplary. FIG. 11 also shows pairs of kerf lines K that define between them the kerf of a saw used to singulate the reconstituted wafer 208.

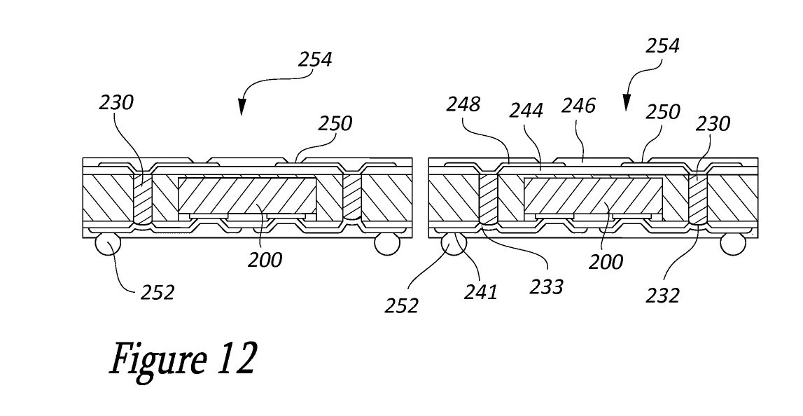

In one embodiment, the final step before singulation is placement of a plurality of solder balls 252 on one or more of the bonding pads 241 on the wafer 208, to form a ball grid array on the front face 203 of the wafer. When all process steps are complete, the wafer 208 is cut into completed packages 254, as shown in FIG. 12.

The processes performed on the bottom face 240 of the wafer 208, as described with reference to FIGS. 10-12, can be performed before, after, or concurrently with any or all of the processes described as following the curing step, with reference to FIGS. 8-11. It may be advantageous to perform similar processes on opposite faces of the reconstituted wafer 208 substantially simultaneously, such as, for example, plating or etching processes. On the other hand, it may be preferable to complete all processes on one side of the wafer 208 prior to reversing the wafer to work on the opposite face. Accordingly, except where the relative order of steps is inherent in the process, or where they are explicitly defined in the claims, the claimed methods are not limited to the order in which their steps are set forth.

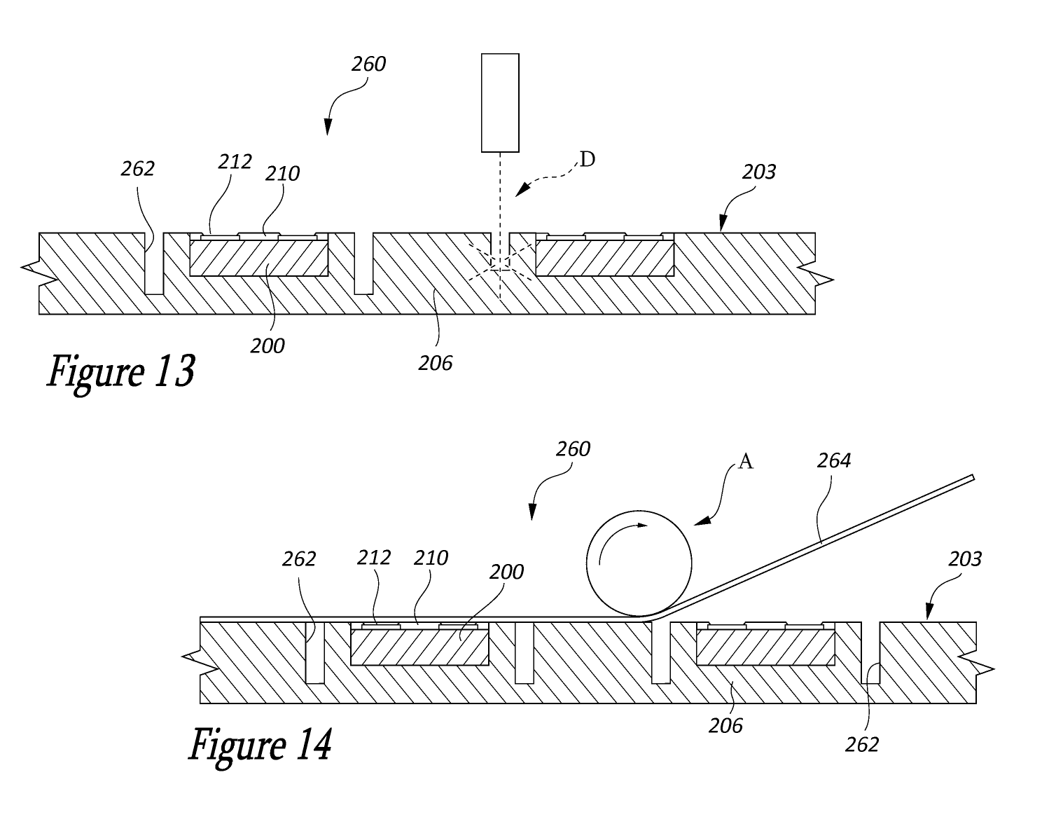

FIGS. 13-16 are diagrammatic cross-sectional views of a portion of a reconstituted wafer 260 according to another embodiment, in which conductive posts are formed in blind apertures, as described hereafter. FIG. 13 shows the wafer 260 at a stage that corresponds to the process steps described above with reference to the wafer 108 in FIG. 5. In this embodiment, blind apertures 262 are formed, using processes similar to those described above. The depth of the apertures is determined according to the requirements of the particular use. Preferably, the apertures have a depth that exceeds a thickness of the semiconductor dies 200, and may be, for example, 100-300 μm in depth. Thus, the aspect ratio of the blind apertures 262 will usually be greater than 5:1, and may exceed 60:1.

As shown in FIG. 14, a dry film layer 264 is adhered to a front face 203 of the MCL 206. According to one method, the dry film 262 is adhered via a rolling process, as depicted in FIG. 14 at A, in which a heated roller applies a controlled pressure to simultaneously warm and press the resist layer of the dry film 264 onto the front face 203 of the MCL 206. According to an alternative process, the film 264 is applied by a vacuum process, in which, with the wafer 260 lying front face up on a planar surface, the film 264 is placed over the wafer, and a sheet of highly conformable elastomeric material, such as, e.g., synthetic rubber, is placed over the film. The sheet of elastomeric material is sealed around its perimeter to the planar surface, and air is drawn out of the space between the elastomeric layer and the planar surface by a vacuum pump. As air is evacuated, the layer of elastomeric material is pressed down onto the front face 203 of the wafer 208 by atmospheric pressure, compressing the layer of dry film 262 against the front face of the wafer. Heat, if required, can be applied by infrared lamps, or by heating the planar surface, or by other appropriate means. Some kinds of dry film resist may not require heat for proper adhesion. Both of these methods are well known for applying dry film to circuit board substrates.

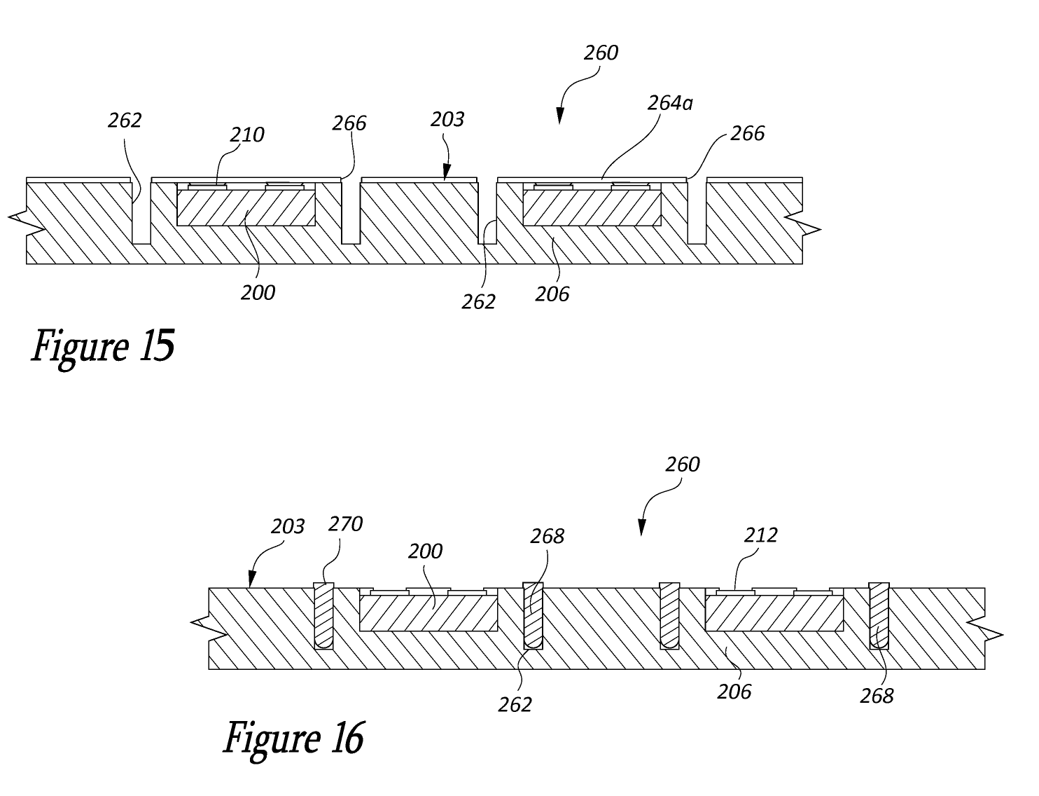

After the dry film resist 262 is adhered to the reconstituted wafer 260, a mask is positioned over the film and the film is exposed through the mask to a light source of an intensity and for a time period that are sufficient to define a selected pattern in the resist layer of the film. The polyester backing of the dry film resist 262 is then removed, and the resist layer 262a that remains on the wafer 260 is processed appropriately to form openings 266 in the resist layer, as best shown in FIG. 15. The mask that is positioned over the film prior to the exposure step is positioned and configured such that processing the film results in formation of openings 266 in the resist layer 262a positioned over respective ones of the blind apertures 262. Dry film resist has the capacity to “tent” over small voids and apertures, so following the application, exposure, and processing of the film, cavities, voids, or apertures in the wafer 260, except those corresponding to openings 266 defined by the mask, are protected by the dry film 262.

After the dry film resist is applied and patterned, conductive paste is introduced into the apertures using, for example, the procedure described above with reference to FIG. 6, except that the paste is applied from the front face of the wafer. It will be recognized that in forcing the conductive paste 224 into the blind apertures 262, an air pocket would normally be trapped within each aperture, preventing the paste from penetrating more than a small distance. In order to overcome this problem, according to one embodiment, the operation in which the paste 224 is applied to the wafer 260 is performed in a low-pressure environment. The paste 224 is applied to the wafer 260 in a chamber from which the air is first evacuated, preferably reducing the atmospheric pressure effectively to zero. Thus, there is little or no air to be trapped within the apertures 262, so the paste 224 can be forced into the apertures by action of the elastomeric blade 228 without trapping air pockets. Additionally, if the wafer 260 is subjected to normal atmospheric pressure before the paste 224 is cured, and if the paste has not penetrated to the bottom of each aperture 262, the return to normal pressure will result in an imbalance of pressure in the apertures, forcing the conductive paste toward the bottom of each aperture. If this results in cavities forming at the tops of the apertures in the uncured paste, the paste application process can be repeated to fill those cavities.

The conductive paste is cured substantially as previously described, forming thereby conductive posts 268, as shown in FIG. 16. The resist layer 264a is then removed using the appropriate solvent or agent, as prescribed by the manufacturer. Front ends 270 of the conductive posts 266 extend a distance above the front surface 203 of the wafer 260 that approximately corresponds to the thickness of the resist layer 264a.

Following removal of the resist layer, the reconstituted wafer 260 is processed to thin the wafer and to form first and second RDL layers on, respectively, the front and back surfaces of the wafer. These steps can be performed using any of a number of known processes, including, e.g., the processes described above with referenced to FIGS. 8-12. In this case, in thinning the wafer, sufficient material is removed from the back surface of the wafer to expose the apertures 262 and the conductive posts 268 formed therein, so that the second RDL can make electrical contact with the back ends of the posts.

While principles of the invention are described with reference to the structures illustrated in FIGS. 2-16, it will be recognized that embodiments are not limited to the specific structures disclosed. For example, the particular structure and configuration of the RDL layers, the formation of the molding compound layer, the thickness of the reconstituted wafer, and the formulation of the conductive paste are all subject to variations according to well known criteria.

Devices that are formed on semiconductor material substrates are generally formed on only one surface thereof, and actually occupy a very small part of the total thickness of the substrate. This surface is generally referred to as the active, front, top, or upper surface. Likewise, for the purposes of the present disclosure and claims, the terms front and back are used to establish an orientation with reference to a semiconductor wafer or die. For example, where a device includes a semiconductor die, reference to a front face of some element of the device can be understood as referring to the surface of that element that would be uppermost if the device as a whole were oriented so that the active surface of the die was the uppermost part of the die. Of course, a bottom or back surface of an element is the surface that would be lowermost, given the same orientation of the device. Use of such terms in the claims to refer to an element of such a device is not to be construed as indicating an actual physical orientation of the element, the device, or the associated semiconductor component, and, where used in a claim, does not limit the claim except as explained above.

The term over is used in the specification and claims to refer to the relative positions of two or more elements with respect to a third element, although the third element may be implied by the context. The term on is used to refer to a physical relationship between two elements. Neither term should be construed as requiring direct physical contact between the elements, nor should they be construed as indicating any particular orientation, either absolute, or with respect to the third element. So, for example, if a claim recites a second layer positioned over a first layer on a substrate, this phrase indicates that the second layer is coupled to the substrate and that the first layer is between the second layer and the substrate. It does not indicate that the layers are necessarily in direct physical contact with each other or with the substrate, but may instead have one or more intervening layers or structures. It also does not indicate that the substrate is oriented in a manner that places the second layer physically above the first layer, nor that, for example, the layers are positioned over a top face of the substrate, as that term is used herein.

The term patterning is commonly used in the art to refer to any of a number of subtractive processes used to define a specific image or pattern in a layer. According to one process, for example, a metallic layer is deposited on a substrate, a positive-acting photosensitive etch resist layer is deposited over the metallic layer, a photo mask is positioned over the resist layer, and the resist layer is exposed through the mask to a light source for a prescribed period, so that some portions of the resist layer are prevented from being exposed by the image of the mask. The resist layer is processed to remove the exposed portions of the layer, which in turn exposes the surface of the metallic layer at those locations. The substrate is processed in a chemical that dissolves the material of the metallic layer, so that the exposed portions of the metallic layer are removed. Lastly, the resist layer is removed, leaving portions of the metallic layer in the form of the image. This process is one of many different processes by which an object or layer can be patterned, and in many, but not all cases, the selection of one process over another is merely a design choice, where any of several processes would be satisfactory. Because such processes are generally well known and understood, they are not described in detail where the choice of process is not material to the disclosure.

Ordinal numbers are used in the specification and claims to distinguish between elements so referenced. There is no necessary significance to the value of a number assigned to one element relative to other numbered elements. Furthermore, an ordinal number used to refer to an element in the claims does not necessarily correlate to a number used to refer to an element in the specification on which the claim reads. Nor does an ordinal number used to refer to a given element in one claim necessarily correlate with a number used to refer to a similar or corresponding element in an unrelated claim—obviously, where a claim refers to a numbered element of a claim from which it depends, the numbers will correspond.

The aspect ratio of an aperture is the depth of the aperture relative to its width or diameter. An aspect ratio of greater than 1:1 is typically referred to as a high aspect ratio, while a low aspect ratio is a ratio of less than 1:1.

The term couple, as used in the claims, includes within its scope indirect coupling, such as when two elements are coupled with one or more intervening elements, even where no intervening elements are recited.

Molding compounds are substances used to encapsulate semiconductor devices in many different packaging processes, are typically composite materials made from blends of ingredients such as, e.g., resins, hardeners, silicas, catalysts, pigments, and release agents, and are generally provided in a substantially liquid form of a selected viscosity so that they can be injected or poured. Molding compounds are available in a very wide range of formulations from different manufacturers and to meet many different criteria. Accordingly, the term molding compound is to be construed broadly to apply to all such compounds.

The unit symbol “μm” is used herein to refer to a value in microns. One micron is equal to 1×10⁻⁶ meters.

The abstract of the present disclosure is provided as a brief outline of some of the principles of the invention according to one embodiment, and is not intended as a complete or definitive description of any embodiment thereof, nor should it be relied upon to define terms used in the specification or claims. The abstract does not limit the scope of the claims.

U.S. patent application Ser. No. 12/977,697, entitled METHOD FOR PRODUCING VIAS IN FAN-OUT WAFERS USING DRY FILM AND CONDUCTIVE PASTE, AND A CORRESPONDING SEMICONDUCTOR PACKAGE, filed on Dec. 23, 2010, is directed to subject matter that has some technical overlap with the subject matter of the present disclosure, and is incorporated herein by reference, in its entirety. The subject matter of the present disclosure and that of the above referenced application were both subject to an obligation to assign to a common assignee at the time the respective inventions were made.

Elements of the various embodiments described above can be combined, and further modifications can be made, to provide further embodiments without deviating from the spirit and scope of the invention. All of the U.S. patents, U.S. patent application publications, U.S. patent applications, foreign patents, foreign patent applications and non-patent publications referred to in this specification are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification, but should be construed to include all possible embodiments along with the full scope of equivalents to which such claims are entitled. Accordingly, the claims are not limited by the disclosure.

1. A method, comprising:
forming a plurality of apertures extending through a reconstituted wafer in which a plurality of semiconductor material dice are embedded, front faces of each of the dice being exposed at a front face of the wafer;
applying a quantity of conductive paste to a back face of the reconstituted wafer;
wiping the quantity of conductive paste across the back face of the wafer and forcing a column of the paste into each of the plurality of apertures;
controlling each column of paste to pass along the respective aperture until a front end of the column lies within a selected distance of the front face of the reconstituted wafer;
curing the conductive paste in the plurality of apertures to form a plurality of conductive posts extending through the wafer; and
forming a redistribution layer on the front face of the wafer, including forming a plurality of electrically conductive traces, a portion of each of the traces making physical and electrical contact with a respective one of the conductive posts.

2. The method of claim 1, comprising forming a redistribution layer on the back face of the wafer.

3. The method of claim 1, comprising thinning the wafer from the back face to a selected thickness.

4. The method of claim 1 wherein forming the redistribution layer comprises forming a plurality of contact pads on the front face of the wafer, and placing a solder ball at each of the contact pads.

5. The method of claim 1 wherein the controlling each column comprises adjusting one or more characteristics of the conductive paste, selected from among: viscosity, rheology, surface tension, and solid content.

6. The method of claim 1 wherein the controlling each column comprises selecting a diameter of the apertures.

7. The method of claim 1 wherein the wiping the quantity of conductive paste comprises placing a resilient elastomeric blade of a squeegee against the back face of the reconstituted wafer and with it pulling a bead of conductive paste across the back face over openings of each of the plurality of apertures, thereby forcing conductive paste into each of the apertures.

8. The method of claim 7 wherein the controlling each column comprises adjusting one or more of: speed at which the squeegee moves across the reconstituted wafer, pressure applied to the blade against the reconstituted wafer, and angle of the squeegee relative to the back face of the reconstituted wafer.

9. The method of claim 7 wherein the controlling each column comprises selecting a hardness of the resilient elastomeric blade.

10. The method of claim 1 wherein the controlling each column comprises applying a vacuum pressure to the front face of the reconstituted wafer and drawing the conductive paste into the plurality of apertures.

11. The method of claim 10 wherein the controlling each column comprises adjusting one or more of: a strength of the vacuum pressure, timing of the applying relative to the wiping, and duration of the applying.

12. A method, comprising:
forming a plurality of apertures extending through a thickness of a semiconductor wafer;
depositing a quantity of conductive paste on the back surface of the semiconductor wafer;
forcing a portion of the quantity of conductive paste into each of the plurality of apertures to form a column of conductive paste within each aperture; and
controlling a volume of the portion forced into each of the plurality of apertures so that a front end of each column lies within a selected distance of a front face of the semiconductor wafer.

13. The method of claim 12, comprising curing the column of conductive paste in each of the plurality of apertures to form a respective conductive post extending substantially from the back face to the front face.

14. The method of claim 13, comprising forming a redistribution on the front face, including forming conductive traces in electrical contact with each of the conductive posts.

15. The method of claim 13, comprising forming a redistribution on the back face, including forming conductive traces in electrical contact with each of the conductive posts.

16. The method of claim 12 wherein the semiconductor wafer is a reconstituted wafer comprising a plurality of semiconductor dice embedded in a molding compound layer.
